(19) United States
(12) Patent Application Publication
(10) Pub. No.: US 2014/0247054 A1
(43) Pub. Date: Sep. 4, 2014

(54) LOW IMPEDANCE NEUTRAL AND DIAGNOSIS

(71) Applicant: Caterpillar Inc., Peoria, IL (US)

(72) Inventor: Brian Joseph Huber, Carpentersville, IL (US)

(73) Assignee: Caterpillar Inc., Peoria, IL (US)

(21) Appl. No.: 14/279,701

(22) Filed: May 16, 2014

(51) Int. Cl. G01R 31/02; G01R 31/34

(52) U.S. Cl. CPC G01R 31/025; G01R 31/34
USPC 324/510

(57) ABSTRACT

A method to diagnose and localize parasitic voltages in an electric drive train is provided. The method includes manipulating a multiplexer to sequentially connect multiple diagnostic locations to a generator neutral, at predefined intervals. A voltage sensor senses a voltage transmission through a lead line that connects the multiplexer to the generator neutral. The voltage sensor generates a voltage signal and delivers that voltage signal to a controller, which compares the voltage signal to a predefined voltage threshold stored within. If the voltage signal exceeds the voltage threshold, the controller determines a parasitic voltage. Based on the location data of the diagnostic locations and the predefined intervals, the controller identifies at least one diagnostic location that experiences the parasitic voltage. Finally, the controller provides feedback in regard to the diagnostic location that experiences the parasitic voltage using the feedback interface.

### TECHNICAL FIELD

The present disclosure relates generally to diagnosing ground faults within electric drive trains in electrically driven machines. More specifically, the present disclosure relates to using a low impedance circuit to diagnose ground faults.

### BACKGROUND

Off-highway trucks, such as Large Mining Trucks (LMT's), are relatively large machines that operate under rigorous operating conditions. These machines usually include numerous systems and sub-systems. Given their size and uninterrupted usage, electrical LMTs frequently develop vulnerabilities towards a voltage fault or parasitic current over time. Apart from general wear and tear, component degradation, and reduced efficiency, unmonitored exposure to voltage faults may lead to significant performance degradation and possible machine downtime. Voltage or current fault may result from insulation degradation, moisture entrapment, and erroneous re-fitting and replacement of conductive parts during service and repairs.

Fundamentally, electric current always flows from a high potential point to a low potential point. To ensure electric faults, such as short-circuits, lightning, and/or electronic noise, do not endanger life and property, industry has responded by adopting a fault grounding method. Principally, a fault grounding method includes channeling electric faults, with minimum voltage drop, to the earth. This is because a conductive mass of the earth's electric potential at any point is usually zero.

Currently employed fault grounding techniques in electrical LMTs employ neutral lines, which have considerably high impedance. Their impedance characteristics, however, tend to be insensitive to relatively low parasitic currents and may not be detectable with the high impedance system. Accordingly, comprehensive detection of parasitic fields over a relatively complex electrical LMT structure having many potential sites for parasitic losses is challenging to develop and would be expensive to implement. Therefore, diagnosing voltage faults effectively and accurately stands as a need among varying industrial applications.

U.S. Pat. No. 7,986,500 patent, discloses a method in an ungrounded system to detect a line-ground fault, in a circuit path to ground through a collection of sequentially switched resistors. A high impedance line and a low impedance line are switched alternatively and a current is measured between a power system's neutral point and ground to detect stray current. If ground fault current is detected then localization of the ground fault is initiated. This reference may provide a means to neutralize parasitic current, however in complicated systems there may be an increased need for diagnostic and troubleshooting capability in addition to a robust neutralization process at a reasonable cost.

### SUMMARY

Various aspects of the present disclosure direct to a parasitic voltage diagnosis and localization system. The system includes a multiplexer having a number of diagnostic centers respectively connect to a set of diagnostic locations. A lead line connects these diagnostic locations to a generator neutral. The parasitic voltage diagnosis and localization system includes a voltage sensor connected to the lead line, and a controller that connects to both the multiplexer and the voltage sensor. The controller stores location data for each of the diagnostic locations. To diagnose and localize parasitic voltages, the controller manipulates the multiplexer to connect each of the diagnostic locations to the generator neutral. Those connections occur at predefined intervals. During each connection, the voltage sensor senses voltage transmissions through the lead line. Alongside every sensed voltage transmission, the voltage sensor generates a voltage signal and delivers the voltage signal to the controller. Upon receipt of the voltage signal, the controller compares the voltage signal to a predefined voltage threshold stored within. A parasitic voltage is determined if the voltage signal exceeds the predefined voltage threshold. Thereafter, the controller identifies the diagnostic location that experiences the parasitic voltage based on the location data of the diagnostic locations and the predefined intervals. A feedback interface connects to the controller, which provides feedback in regard to the diagnostic location that experiences the parasitic voltage.

Certain aspects of the present disclosure also direct to a parasitic voltage diagnosis and localization system that diagnoses voltage faults in an electric drive train of an electric Large Mining Truck (LMT). The system includes a multiplexer that includes a number of diagnostic centers. Each diagnostic center connects to a set of diagnostic locations. The multiplexer also connects those diagnostic locations to a generator neutral via a lead line. More particularly, the multiplexer is configured to manipulate the connection between the diagnostic locations to the generator neutral, sequentially, with each connection occurring at predefined intervals. A controller connects to the multiplexer to enable the sequential connection. Further, a voltage sensor also associates to the controller and connects to the lead line to sense a voltage transmission there through. Having sensed a voltage transmission, the voltage sensor generates a voltage signal and delivers that voltage signal to the controller. The controller stores a predefined threshold voltage and a location data of each of the diagnostic locations. Upon receipt of the voltage signal, the controller compares the received voltage signal to the predefined threshold voltage to determine a parasitic voltage if the sensed voltage signal exceeds the predefined threshold voltage. Moreover, the controller identifies the diagnostic location that experiences the parasitic voltage. That identification is based on the stored location data of each diagnostic location and predefined intervals. A feedback interface connects to the controller and is configured to provide feedback when a diagnostic location experiences the parasitic voltage.

### BRIEF DESCRIPTION OF THE DRAWINGS

FIG. 1 is a schematic of an exemplary electric Large Mining Truck (LMT), in accordance with the concepts of the present disclosure;

FIG. 2 is an exemplary parasitic voltage diagnosis and localization system, in accordance with the concepts of the present disclosure; and

FIG. 3 is a flow chart illustrating an exemplary method for diagnosing and localizing parasitic voltages, in accordance with the concepts of the present disclosure.

### DETAILED DESCRIPTION

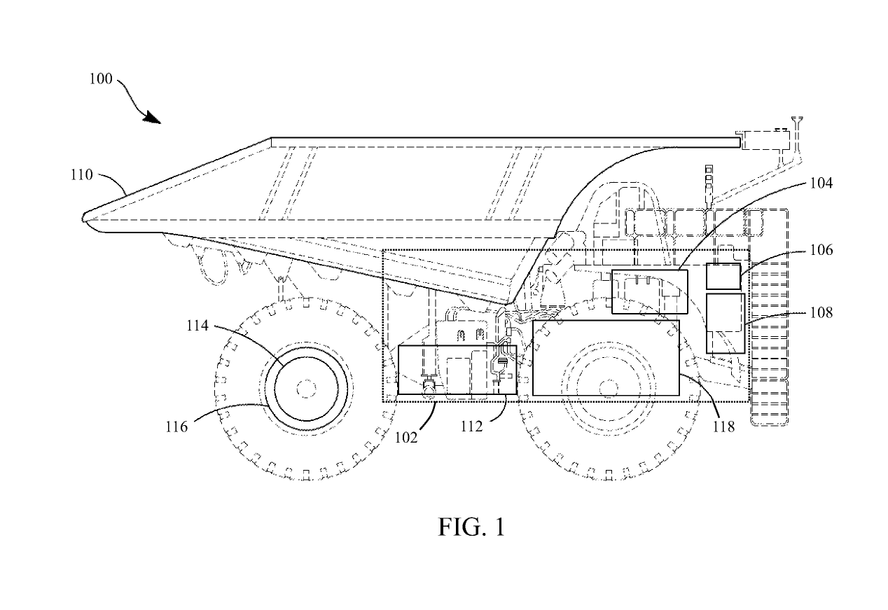

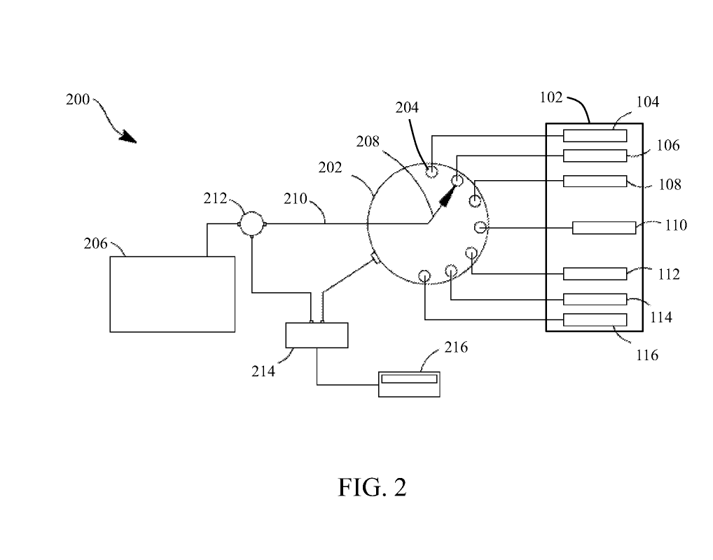

FIG. 1 is a schematic of an exemplary electric Large Mining Truck (LMT) 100, hereafter referred to as LMT, in accordance with the concepts of the present disclosure. With reference to FIG. 1, the LMT 100 is an electrically operated machine having an electric drive train 102. The electric drive train 102 includes a motor having a frame 104, an inverter having a frame 106, a grid having a frame 108, the truck having multiple frames 110 and 112, a race bearing 114, and a driveshaft housing 116. Also included in the electric drive train 102 is a generator 118 that has a generator neutral 206 (shown in FIG. 2).

Each disclosed component within the electric drive train 102 requires regular fault monitoring. Therefore, the electric drive train 102 is operably employed within a parasitic current or voltage diagnosis and localization system as set out in the forthcoming disclosure. For ease in reference, each component within the electric drive train 102 is referred to as a diagnostic location.

Adding components for diagnosis to the electric drive train 102 is contemplated. Accordingly, the electric drive train 102 may also include rectifiers, converters, dynamic braking grids, blowers, etc. (not shown).

FIG. 2 is an exemplary parasitic current or voltage diagnosis and localization system 200, in accordance with the concepts of the present disclosure. FIG. 2 is explained in conjunction with elements from FIG. 1. With reference to FIG. 2, the parasitic voltage diagnosis and localization system 200 includes a multiplexer 202, with diagnostic centers 204. The diagnostic centers 204 correspondingly connect to each diagnostic location of the electric drive train 102. A switch 208 within the multiplexer 202 facilitates those connections. Another lead line 210 connects the multiplexer 202 to a generator neutral 206, as shown. Additionally, a current or voltage sensor 212 is positioned en route to the generator neutral 206. Both the multiplexer 202 and the voltage sensor 212 are connected to a controller 214, which in turn operably links to a feedback interface 216 to provide a diagnosis feedback.

The multiplexer 202 may be an analog device that selects multiple input signals under predetermined or predefined intervals and perhaps in a sequential fashion, for example, to enhance an aggregate data transmission towards a selected recipient. In an exemplary embodiment, input signals may be transmitted sequentially from one of the diagnostic locations, and may be sent to the generator neutral 206 that act as the selected recipient. Each diagnostic center 204 may include digital addresses of corresponding diagnostic locations. Those digital addresses may be fed and stored within the controller 214 (discussed later). The multiplexer 202 may be a 5V Time Division Analog Multiplexer. Nonetheless, an application involving a digital multiplexer may be also contemplated. As and when additions are made to the component set, the multiplexer 202 may be configured to include additional diagnostic centers 204 and related connection provisions. Moreover, those having ordinary skill in the art of multiplexer design may contemplate alternative arrangements and structural layouts within the multiplexer 202.

The switch 208 is arranged within the multiplexer 202 and is linked operably to the controller 214 to receive input. The multiplexer 202 receives preset signals to manipulate the switch 208 for varying connections in the network. With every movement, the switch 208 disconnects a prior diagnostic center 204 and establishes a new connection with a succeeding diagnostic center 204. Specifically, the switch's connection to a diagnostic center 204 electrically links a corresponding diagnostic location to the generator neutral 206. In affect, the switch 208 is configured to sequentially open and close a live connection between one of the diagnostic locations and the generator neutral 206.

Connections between each diagnostic location and the generator neutral 206 occur by switch closures at every diagnostic center 204. Each switch closure accompanies a predefined interval for which a diagnosis is performed, and therefore, closed connections are maintained for a set time. During an exemplary start, the switch 208 may first close a connection between the motor frame 104 and the generator neutral 206 for a period of 5 minutes. During that period, fault diagnosis may be continuously performed and every incident of a voltage transmission may be registered. After 5 minutes, the switch 208 opens the connection between the motor frame 104 and the generator neutral, and moves to close a succeeding connection between the inverter frame 106 and the generator neutral 206, again for a similar 5 minute period. The switch 208 moves in a subsequent fashion to reach all diagnostic centers 204 for closing subsequent connections, and then, repeats the cycle till the parasitic voltage diagnosis and localization system 200 is deactivated. Closure periods that differ for each diagnostic location may be contemplated as well. For that purpose, the controller 214 may be recalibrated or reprogrammed with specific closure periods based on location.

Switch 208 may be a stepper motor, or other switching device having a discretely positionable switch or any other known switching device within a multiplexer is contemplated.

The voltage sensor 212 may be any of the widely applied sensors in the art capable of sensing voltage transmissions through the lead line 210. The voltage sensor 212 may be retrofitted to the lead line 210. More particularly, the voltage sensor 212 is configured to sense voltage transmissions, convert the sensed voltage into a readable signal, and deliver that signal to the controller 214.

The controller 214 connects to both the voltage sensor 212 and the multiplexer 202 via a lead line, such as the lead line 210. The controller 214 may include a timer (not shown) to track the period for which the switch 208 remains in engagement with each diagnostic center 204. The parasitic voltage diagnosis and localization system 200 may include memory (not shown) which is configurable to retrieve and store data, which may have been gathered at the diagnostic centers 204 relative to the devices connected to such centers. Another connection, which extends from the controller 214, defines an operable link to the feedback interface 216.

The controller 214 may be a microprocessor-based device configured to receive sensed voltage signals from the voltage sensor 212. Subsequent to receiving the signal, the controller 214 processes the received signal and converts the signal into a feedback-specific format, compatible for a delivery to the feedback interface 216.

The controller 214 may include a set of volatile memory units such as RAMs/ROMs, which include associated input and output buses. More particularly, the controller 214 may be envisioned as an application-specific integrated circuit, or other logic devices, which provide controller functionality, and such devices being known to those with ordinary skill in the art. In an exemplary embodiment, the controller 214 may form a portion of one of the machine's electronic control unit (ECU), such as a safety module or a vehicle dynamics module, or may be configured as a stand-alone entity. The controller 214 may be configured into the LMT's (100) dashboard to impart functionality and service convenience. Further exemplary arrangements may include the controller's accommodation within other machine panels or portions from where the controller 214 remains accessible for ease of use, service, and repairs.

The controller 214 stores information that pertains to the timer and defines a set period for every connection between the diagnostic location and the generator neutral 206. Also stored within the controller 214 are predefined voltage threshold values that benchmark detected voltage transmission. It is envisioned that an operator may control or re-calibrate the controller 214 to differing standards of timing schedules and voltage threshold magnitudes.

The controller 214 also stores location data (such as digital addresses) of each diagnostic location within the controller's memory. More particularly, factoring a diagnostic location determination is the predefined interval, which is set for each diagnostic location. Accordingly, each time slot corresponds to a diagnostic location. As shown in FIG. 2, if there are 7 diagnostic locations, then spending 5 minutes on every diagnostic center equates to a 35 minute diagnosis cycle time. If threshold breaching voltage transmissions are detected between the 15-20 minute period, the controller 214 identifies truck frame 110 (fourth component in the list) as the diagnostic location associated with the parasitic voltage. It is envisioned that the present disclosure parasitic voltage diagnosis and localization system 200 may accommodate additional diagnostic centers 204, which may be included, and each may correspond to a new diagnostic locations, for example. The controller 214 may have functionality to stack the data (digital addresses) of such additional diagnostic centers.

The feedback interface 216 provides either a visual display or an audible output of a gauged diagnosis (or both if desired). An exemplary visual display may include providing comprehensible images and/or digitized values to an operator. Though a screen-based feedback is typically preferred, analog-based feedback may be provided as well. For example, a dial gauge provided to a machine operator with visual blinkers may indicate the presence of voltage faults within the parasitic voltage diagnosis and localization system 200. An audible feedback may include speakers installed within the LMT 100, at designated locations to provide an audible feedback, such as an alarm or a prerecorded warning message. A combination of both an audible and a visual output may be provided as well. In an embodiment, the feedback interface 216 may be integrated to machine dashboard where an operator may readily receive feedback. In an exemplary embodiment, the feedback interface 216 may be connected to other sub-systems within the LMT 100, to provide communication of such subsystems through the feedback interface 216.

Dependent upon the environment, known provisions may be set within the parasitic voltage diagnosis and localization system 200 for initiating an automatic start/stop. Alternatively, a machine operator may manually activate and/or deactivate the parasitic voltage diagnosis and localization system 200, when not in use, to minimize power consumption.

In an exemplary embodiment, the parasitic voltage diagnosis and localization system 200 may be production installed in the LMT 100 or configured as a portable installable kit, which enhances fault diagnosis usability among varying industrial applications.

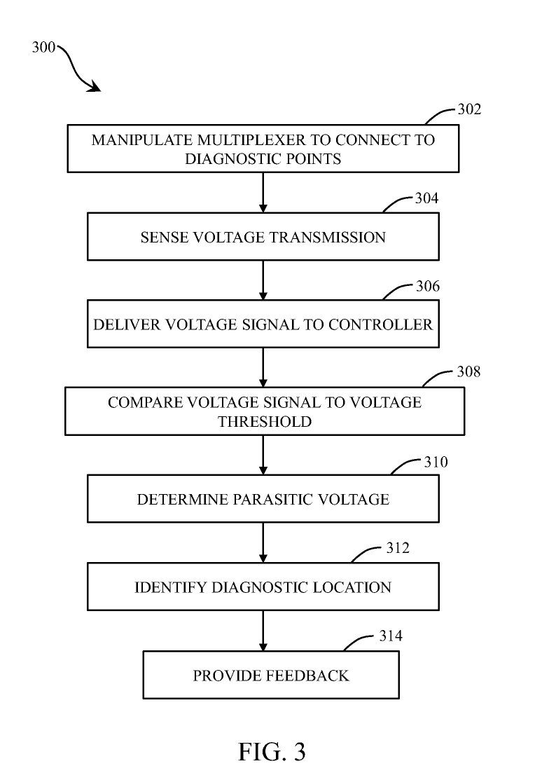

FIG. 3 is a flow chart 300 illustrating a method for diagnosing and localizing parasitic voltages, according to the concepts of the present disclosure. FIG. 3 is explained in conjunction with elements from FIG. 1 and FIG. 2. With reference to FIG. 3, the method begins with step 302.

At step 302, the controller 214 manipulates the multiplexer 202 to start a sequential connection between each diagnostic location and the generator neutral 206. The switch 208 closes the diagnostic center 204 that corresponds to the first diagnostic location (motor frame 104) and connects the motor frame 104 to the generator neutral 206. The method proceeds to step 304.

At step 304, the voltage sensor 212 senses voltage transmissions and communicates the same through the lead line 210 and proceeds to register all voltage flows, and converts each flowing voltage into a voltage signal. The method proceeds to step 306.

At step 306, the voltage sensor 212 communicates the voltage signal to the controller 214. The method proceeds to step 308.

At step 308, the controller 214 compares the detected voltage signal to the predefined voltage threshold stored within. The detected voltage signal may be lower, higher, or equal to the predefined voltage threshold. The method proceeds to step 310.

At step 310, if the detected voltage signal is less than the predefined voltage threshold, the controller 214 ignores the voltage signal. If the voltage signal exceeds the voltage threshold, the controller 214 determines a parasitic voltage. The method proceeds to step 312.

At step 312, the controller 214 identifies the diagnostic location corresponding to the parasitic voltage. Identification of diagnostic location may be based on the data stored within the controller 214, such as stored location data (digital address) and every corresponding diagnostic location will have a corresponding set of data. The controller 214 moves to subsequent locations at predefined intervals. The method proceeds to step 314.

At step 314, the controller 214 provides the identified data to the feedback interface 216, which displays or notifies an operator audibly of the affected diagnostic location.

Once a predefined interval has elapsed, the switch 208 opens the connection between the first diagnostic location and the generator neutral 206 and moves to close a connection between a succeeding diagnostic location and the generator neutral 206. The process continues until the last diagnostic location is monitored for voltage and repeats the cycle until the parasitic voltage diagnosis and localization system 200 is deactivated.

### INDUSTRIAL APPLICABILITY

During operations, the controller 214 manipulates the multiplexer 202. Manipulation includes establishing a live connection between the generator neutral 206 and each diagnostic location, sequentially, with each connection being set for a predefined interval. For every connection, the voltage sensor 212 senses a voltage transmission through the lead line 210. More specifically, the voltage sensor 212 generates a voltage signal alongside every voltage transmission. Next, the voltage sensor 212 delivers the voltage signal from voltage sensor to the controller 214. Once delivered, the controller 214 compares the voltage signal to the predefined voltage threshold stored therein and determines if there is a parasitic voltage if the voltage signal exceeds the voltage threshold. Thereafter, the controller 214 identifies the diagnostic location that experiences the parasitic voltage by matching the location data associated with each of the diagnostic centers 204 and determines subsequent diagnostic locations by using the predefined interval set on the multiplexer corresponding to each diagnostic location. Subsequently, the controller 214 delivers the identified data to the feedback interface 216, which delivers the data to an operator or a sub-system within the LMT 100. Feedback may be provided by an LCD screen, touch screen, visual display, audible format, etc. Embodiments may include a tactile feedback provided to an operator every time a voltage threshold is breached. In further implementations, parasitic voltages may be delivered to exemplary sub-systems such as an internal fault logging system, official email IDs, or other remote locations as is desired.

It should be understood that the above description is intended for illustrative purposes only and is not intended to limit the scope of the present disclosure in any way. Thus, those skilled in the art will appreciate that other aspects of the disclosure may be obtained from a study of the drawings, the disclosure, and the appended claim.

What is claimed is:

1. A method to diagnose and localize parasitic voltages in an electric drive train, the electric drive train having a parasitic voltage diagnosis and localization system that includes a multiplexer having diagnostic centers respectively connect to a plurality of diagnostic locations, the multiplexer in turn connecting the plurality of diagnostic locations to a generator neutral via a lead line, the parasitic voltage diagnosis and localization system including a voltage sensor connected to the lead line, and a controller connecting to both the multiplexer and the voltage sensor, wherein the controller stores a location data of the plurality of diagnostic locations, and in turn connects to a feedback interface, the method comprising:
manipulating the multiplexer to connect the plurality of diagnostic locations to the generator neutral at predefined intervals, the connection being facilitated by the controller;
sensing a voltage transmission through the lead line by using the voltage sensor and correspondingly generating a voltage signal;
delivering the voltage signal from the voltage sensor to the controller;
comparing the voltage signal to a predefined voltage threshold stored within the controller;
determining a parasitic voltage if the voltage signal exceeds the predefined voltage threshold;
identifying at least one diagnostic location among the plurality of diagnostic locations that experiences the parasitic voltage, the identification being based on the location data of the plurality of diagnostic locations and the predefined intervals; and:
providing a feedback on at least one of the plurality of diagnostic locations that experiences the parasitic voltage, using the feedback interface.

2. A parasitic voltage diagnosis and localization system for an electric drive train of Large Mining Truck (LMT), the system comprising:
a multiplexer, having diagnostic centers connect a plurality of diagnostic locations on the LMT, the multiplexer in turn connecting the plurality of diagnostic locations to a generator neutral via a lead line, wherein:
the multiplexer is configured to manipulate the connection between the plurality of diagnostic locations to the generator neutral at predefined intervals, the connection occurring sequentially;
a voltage sensor, connected to the lead line to sense a voltage transmission there through, and correspondingly generate a voltage signal;
a controller, connected to the voltage sensor to receive the voltage signal, and to the multiplexer for facilitating the sequential connection between the plurality of diagnostic locations to the generator neutral, wherein:
the controller stores a predefined voltage threshold and a location data of the plurality of diagnostic locations, and compares the voltage signal to the predefined voltage threshold to determine a parasitic voltage, the controller identifying at least one diagnostic location among the plurality of diagnostic locations that experiences the parasitic voltage based on the location data of the plurality of diagnostic locations and the predefined intervals; and
a feedback interface, connected to the controller configured to provide feedback when a diagnostic location experiences the parasitic voltage.
